(19) United States
(12) Patent Application Publication
(10) Pub. No.: US 2026/0100339 A1
(43) Pub. Date: Apr. 9, 2026

(54) Grounded Slit Door for Substrate Process Chamber

(71) Applicant: Applied Materials, Inc., Santa Clara, CA (US)

(72) Inventors: Yogananda Vishwanath SARODE, Bangalore (IN); Srikantha RAJU, Bangalore (IN); Kiran Shyam HONNAVAR, Bangalore (IN); Larry D. ELIZAGA, Tracy, CA (US); James David CARDUCCI, Sunnyvale, CA (US); Silverst Antony RODRIGUES, San Jose, CA (US); Michael R. RICE, Pleasanton, CA (US)

(21) Appl. No.: 18/907,224

(22) Filed: Oct. 4, 2024

(51) Int. Cl. H01J 37/32

(52) U.S. Cl. CPC H01J 37/32522; H01J 2237/002

(57) ABSTRACT

Embodiments of slit door assemblies for use in a process chamber are provided herein. In some embodiments, a slit door assembly comprises: a slit door having an arcuate profile and a first surface comprising a plasma facing surface and a second surface opposite the first surface, and wherein at least one of: the first surface or the second surface includes a recessed portion along a peripheral edge thereof; or the slit door has an annular shape; and an actuator assembly coupled to the slit door and configured to move the slit door in a vertical direction, wherein the actuator assembly includes a plurality of rods coupled to the slit door, wherein one or more of the plurality of rods include a cooling channel extending to the slit door or a heater.

### FIELD

Embodiments of the present disclosure generally relate to substrate processing equipment.

### BACKGROUND

Deposition and etch chambers used in the manufacturing of semiconductor devices need to produce consistent and uniform results for every substrate that is processed. To further enhance processing, plasma can be used in both deposition and etching of materials. The plasma can be generated through inductive coupling or capacitive coupling. In capacitively coupled plasma chambers, liners are used to contain the plasma generated in a process volume of the chamber and to provide an RF ground return path. The liners generally surround the process volume except at locations interrupted by substrate transfer slots. The substrate transfer slots allow robotic arms to place substrates into and out of the process volume of the plasma chamber. The inventors have observed, however, that the presence of the transfer slot interferes with the uniformity of the deposition or etching on the substrate during processing.

Thus, the inventors have provided improved methods and apparatus that increase deposition or etch uniformity on substrates.

### SUMMARY

Embodiments of slit door assemblies for use in a process chamber are provided herein. In some embodiments, a slit door assembly comprises: a slit door having an arcuate profile and a first surface comprising a plasma facing surface and a second surface opposite the first surface, and wherein at least one of: the first surface or the second surface includes a recessed portion along a peripheral edge thereof; or the slit door has an annular shape; and an actuator assembly coupled to the slit door and configured to move the slit door in a vertical direction, wherein the actuator assembly includes a plurality of rods coupled to the slit door, wherein one or more of the plurality of rods include a cooling channel extending to the slit door or a heater.

In some embodiments, a process kit for use in a process chamber includes: a liner having an annular shape and a transfer slot; and a slit door assembly, comprising: a slit door having an arcuate profile and a first surface comprising a plasma facing surface and a second surface opposite the first surface; and an actuator assembly coupled to the slit door and configured to move the slit door in a vertical direction to selectively place the slit door in a closed position, where the slit door is in contact with the liner, and an open position, where the slit door is spaced from the liner, and wherein in the closed position, an inner surface of the slit door is substantially flush with an inner surface of the liner to close the transfer slot.

In some embodiments, a process chamber includes: a chamber body defining an interior volume therein, having an opening extending through sidewalls of the chamber body for transferring a substrate, and having a chamber cavity disposed about the opening on an interior surface of the chamber body; a process kit that includes a liner having an annular shape and a transfer slot; and a slit door assembly, comprising: a slit door having an arcuate profile and a first surface comprising a plasma facing surface and a second surface opposite the first surface; and an actuator assembly coupled to the slit door and configured to move the slit door in a vertical direction to selectively place the slit door in a closed position, where the slit door is in contact with the liner, and an open position, where the slit door is spaced from the liner, and wherein in the closed position, an inner surface of the slit door is substantially flush with an inner surface of the liner to close the transfer slot, wherein the transfer slot of the liner is aligned with the opening in the chamber body, and wherein at least one of: the first surface or the second surface includes a recessed portion along a peripheral edge thereof; or the slit door has an annular shape; and a substrate support disposed in the interior volume to support a substrate.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic side view of a portion of a process chamber having a slit door in accordance with some embodiments of the present disclosure.

FIG. 2 depicts an isometric view of a slit door assembly in accordance with at least some embodiments of the present disclosure.

FIG. 3 depicts a cross-sectional view of a slit door and a liner in accordance with at least some embodiments of the present disclosure.

FIG. 4A depicts a cross-sectional view of a slit door and a liner in a closed position in accordance with at least some embodiments of the present disclosure.

FIG. 4B depicts a cross-sectional view of a slit door and a liner in an open position in accordance with at least some embodiments of the present disclosure.

FIG. 5 depicts a schematic back view of a slit door assembly in accordance with at least some embodiments of the present disclosure.

FIG. 6A depicts a schematic cross-sectional side view of a process chamber with a slit door in a closed position in accordance with at least some embodiments of the present disclosure.

FIG. 6B depicts a schematic cross-sectional side view of a process chamber with a slit door in an open position in accordance with at least some embodiments of the present disclosure.

FIG. 7A depicts a schematic cross-sectional side view of a process chamber with an annular slit door in a closed position in accordance with at least some embodiments of the present disclosure.

FIG. 7B depicts a schematic cross-sectional side view of a process chamber with an annular slit door in an open position in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of slit door assemblies for use in process chambers are provided herein. The process chamber may be any suitable process chamber for processing substrate such as an etch or deposition process. The process chamber includes a liner disposed in an interior volume thereof. The slit door assemblies include a slit door that is spaced from the liner in a substrate transfer position and in contact with the liner when in a process position. The slit door in contract, or flush with, the liner advantageously promotes more symmetrical plasma distribution in the interior volume. The slit door can also be advantageously heated or cooled to control a temperature of the liner to increase temperature uniformity between the liner and the slit door.

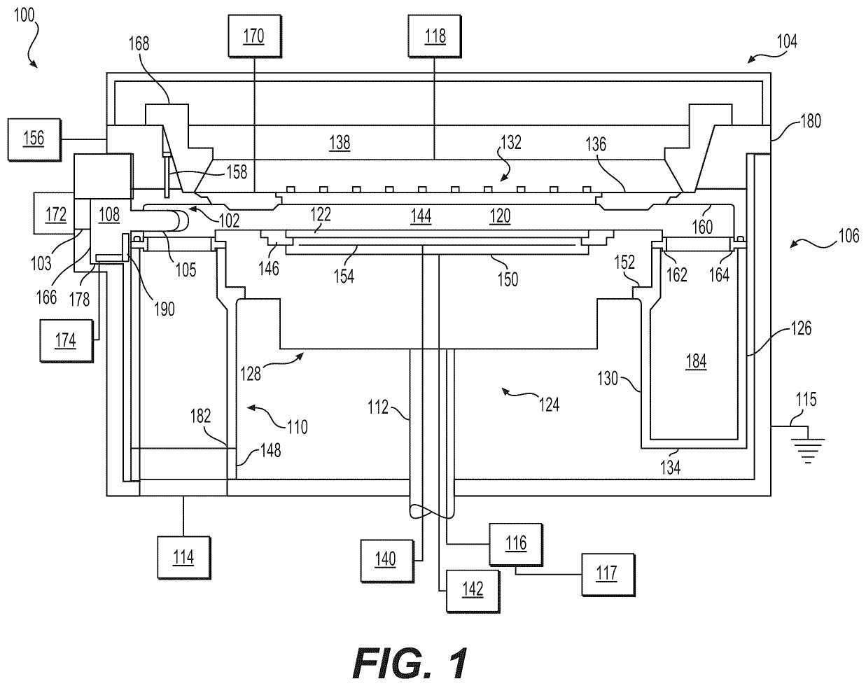

FIG. 1 is a schematic side view of a portion of a process chamber having a slit door in accordance with some embodiments of the present disclosure. In some embodiments, the process chamber is an etch processing chamber. However, other types of processing chambers configured for different processes can use or be modified for use with embodiments of the liners described herein.

The process chamber 100 is a vacuum chamber which is suitably adapted to maintain sub-atmospheric pressures within an interior volume 120 during substrate processing. The process chamber 100 includes a chamber body 106 having sidewalls and a bottom wall. The chamber body 106 is covered by a lid 104 and the chamber body 106 and the lid 104, together, define the interior volume 120. The chamber body 106 and lid 104 may be made of metal, such as aluminum. The chamber body 106 may be grounded via a coupling to ground 115.

A substrate support 124 is disposed within the interior volume 120 to support and retain a substrate 122, such as a semiconductor wafer, for example, or other such substrate as may be electrostatically retained. The substrate support 124 may generally comprise a pedestal 128 and a hollow support shaft 112 for supporting the pedestal 128. The pedestal 128 may include an electrostatic chuck 150. The electrostatic chuck 150 comprises a dielectric plate having one or more electrodes 154 disposed therein. The hollow support shaft 112 provides a conduit to provide, for example, backside gases, process gases, fluids, coolants, power, or the like, to the pedestal 128.

The substrate support 124 is coupled to a chucking power supply 140 and RF sources (e.g., RF bias power supply 117 or RF plasma power supply 170) to the electrostatic chuck 150. In some embodiments, a backside gas supply 142 is disposed outside of the chamber body 106 and supplies heat transfer gas to the electrostatic chuck 150. In some embodiments, the RF bias power supply 117 is coupled to the electrostatic chuck 150 via one or more RF match networks 116. In some embodiments, the substrate support 124 may alternatively include AC or DC bias power.

The process chamber 100 is also coupled to and in fluid communication with a process gas supply 118 which may supply one or more process gases to the process chamber 100 for processing the substrate 122 disposed therein. In some embodiments, a showerhead 132 is disposed in the interior volume 120 opposite the substrate support 124. In some embodiments, the showerhead 132 is coupled to the lid 104. The showerhead 132 and the substrate support 124 partially define a processing volume 144 therebetween. The showerhead 132 includes a plurality of openings to distribute the one or more process gases from the process gas supply 118 into the processing volume 144. The showerhead 132 may be coupled to a temperature control unit 138 to control a temperature of the showerhead 132. In some embodiments, an upper electrode 136 is disposed in the interior volume 120 opposite the substrate support 124 to further define the process volume 144. The upper electrode 136 is coupled to one or more power sources (e.g., RF plasma power supply 170) to ignite the one or more process gases. In some embodiments, the upper electrode 136 comprises silicon.

The process chamber 100 generally includes a process kit to protect chamber components against unwanted deposition or etching. The process kit may include a liner 102, for example a confinement liner, disposed in the interior volume 120 about at least one of the substrate support 124 and the showerhead 132 to confine a plasma therein. In some embodiments, the liner 102 is made of a suitable process material, such as aluminum, a silicon-containing material, or aluminum with ceramic coating. For example, the liner 102 may be made of silicon carbide (SiC), single crystal silicon, polysilicon, or a material coated with silicon carbide (SiC) or polysilicon to advantageously reduce contamination on the substrate 122. The liner 102 includes an upper liner 160 and a plasma screen 162.

The upper liner 160 may be made of any of the materials mentioned above. In some embodiments, the plasma screen 162 is made of the same material as the upper liner 160. For example, the upper liner 160 and the plasma screen 162 may both be made of polysilicon. In some embodiments, the upper liner 160 is made of a material different than the plasma screen 162. For example, in some embodiments, the upper liner 160 is made of aluminum and the plasma screen 162 is made of polysilicon or a material coated with polysilicon or ceramic. In some embodiments, the upper liner 160 is made of silicon carbide (SiC) and the plasma screen 162 is made of polysilicon or a material coated with polysilicon. In some embodiments, the upper liner 160 rests on the plasma screen 162. In some embodiments, the upper liner 160 and the plasma screen 162 are integrally formed. The plasma screen 162 extends radially inward from the upper liner 160 to define a C-shaped cross-sectional profile of the liner 102. In some embodiments, an inner diameter of the upper liner 160 is greater than an inner diameter of the plasma screen 162.

The plasma screen 162 includes a plurality of radial slots 164 arranged around the plasma screen 162 to provide a flow path of the process gases to a pump port 148 (discussed below). In some embodiments, the liner 102, along with the showerhead 132 and the pedestal 128, at least partially define the processing volume 144. In some embodiments, an outer diameter of the showerhead 132 is less than an outer diameter of the liner 102 and greater than an inner diameter of the liner 102. The liner 102 includes a substrate transfer slot 105 aligned with an opening 103 in the chamber body 106 for transferring the substrate 122 into and out of the process chamber 100. In some embodiments, the opening 103 has a width of about 13 inches to about 22 inches. A slit valve 172 is coupled to the chamber body 106 to selectively open or close the opening 103 in the chamber body 106.

The process chamber 100 includes a slit door 190 disposed between the chamber body 106 and the liner 102. In some embodiments, the chamber body 106 includes a chamber cavity 108 disposed about the opening 103 on an interior surface 166 of the chamber body 106. In some embodiments, the slit door 190 is disposed in the chamber cavity 108 and is configured to move within the chamber cavity 108 to selectively expose or cover substrate transfer slot 105 of the liner 102. The slit door 190 is shaped corresponding to a shape of the liner 102. In some embodiments, the slit door 190 has an arcuate profile corresponding to a curvature of the liner 102. In a first position, as shown in FIG. 1, the slit door 190 is positioned to expose the substrate transfer slot 105 of the liner.

The process chamber 100 includes a slit door assembly comprising the slit door 190 coupled to an actuator 174 to facilitate moving the slit door 190 from the first position to a subsequent position to selectively cover or seal the substrate transfer slot 105. In some embodiments, the actuator 174 is configured to move the slit door 190 vertically. In some embodiments, the actuator 174 is configured to move the slit door 190 vertically and horizontally, for example, in an L-motion. In some embodiments, the actuator 174 extends through a ledge 178 of the chamber body 106 defined by the chamber cavity 108.

In some embodiments, the liner 102 is coupled to a heater ring 180 to heat the liner 102 to a predetermined temperature. In some embodiments, the liner 102 is coupled to the heater ring 180 via one or more fasteners 158. A heater power source 156 is coupled to one or more heating elements in the heater ring 180 to heat the heater ring 180 and the liner 102. In some embodiments, a ceramic ring 168 is disposed between the heater ring 180 and the showerhead 132 to thermally de-couple the heater ring 180 from the showerhead 132.

The process chamber 100 is coupled to and in fluid communication with a vacuum system 114, which includes a throttle valve and a vacuum pump, used to exhaust the process chamber 100. The pressure inside the process chamber 100 may be regulated by adjusting the throttle valve and/or vacuum pump. The vacuum system 114 may be coupled to a pump port 148.

In some embodiments, the liner 102 rests on a lower liner 110. The lower liner 110 is configured to direct a flow of the one or more process gases and processing by-products from the plurality of radial slots 164 to the pump port 148. In some embodiments, the lower liner 110 includes an outer sidewall 126, an inner sidewall 130, and a lower wall 134 extending from the outer sidewall 126 to the inner sidewall 130. The outer sidewall 126, the inner sidewall 130, and the lower wall 134 define an exhaust volume 184 therebetween. In some embodiments, the outer sidewall 126 and the inner sidewall 130 are annular. The lower wall 134 includes one or more openings 182 (one shown in FIG. 1) to fluidly couple the exhaust volume 184 to the vacuum system 114. The lower liner 110 may rest on or be otherwise coupled to the pump port 148. In some embodiments, the lower liner 110 includes a ledge 152 extending radially inward from the inner sidewall 130 to accommodate a chamber component, for example, the pedestal 128 of the substrate support 124. In some embodiments, the lower liner 110 is made of a conductive material such as aluminum to provide a ground path.

In operation, for example, a plasma may be created in the processing volume 144 to perform one or more processes. The plasma may be created by coupling power from a plasma power source (e.g., RF plasma power supply 170) to a process gas via one or more electrodes (e.g., upper electrode 136) near or within the interior volume 120 to ignite the process gas and create the plasma. A bias power may also be provided from a bias power supply (e.g., RF bias power supply 117) to the one or more electrodes 154 within the electrostatic chuck 150 to attract ions from the plasma towards the substrate 122.

A plasma sheath can bend at an edge of the substrate 122 causing ions to accelerate perpendicularly to the plasma sheath. The ions can be focused or deflected at the substrate edge by the bend in the plasma sheath. In some embodiments, the substrate support 124 includes an edge ring 146 disposed about the electrostatic chuck 150. In some embodiments, the edge ring 146 and the electrostatic chuck 150 define a substrate receiving surface. The edge ring 146 may be coupled to a power source, such as RF bias power supply 117 or a second RF bias power supply (not shown) to control and/or reduce the bend of the plasma sheath.

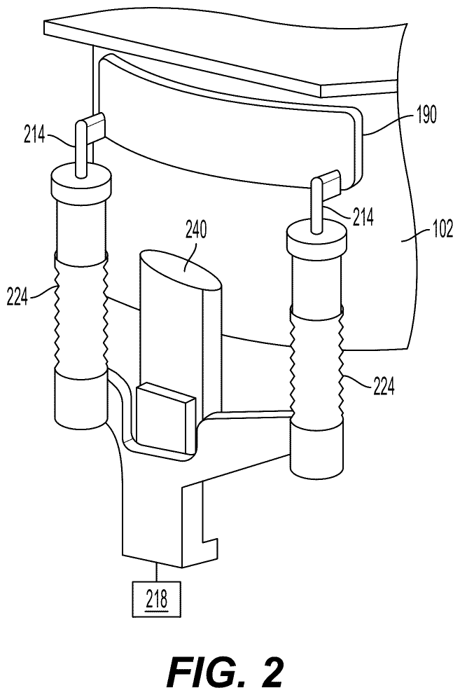

FIG. 2 depicts an isometric view of a slit door assembly 200 in accordance with at least some embodiments of the present disclosure. The slit door assembly 200 generally includes the slit door 190 and an actuator assembly 210 coupled to the slit door 190. The actuator assembly 210 is configured to move the slit door 190 in a vertical direction. In some embodiments, the actuator assembly 210 is configured to move the slit door 190 in a vertical and horizontal direction (e.g., in an L-motion). In some embodiments, the slit door 190 has an arcuate profile. The slit door 190 is generally sized to cover the substrate transfer slot 105 of the liner 102.

In some embodiments, the actuator assembly 210 includes a plurality of rods 214 coupled to the slit door 190 and an actuator 218 coupled to the plurality of rods 214. In some embodiments, the actuator 218 is coupled to a bracket 220 and the bracket 220 is coupled to at least some of the plurality of rods 214. The actuator 218 is configured to move the bracket 220 vertically to move the slit door 190 vertically via the plurality of rods 214. In some embodiments, the bracket 220 is configured to move vertically with respect to a backing plate 240 of the actuator assembly 210 that is, for example, coupled to chamber body 106. In some embodiments, the bracket 220 includes a central body 228 coupled to the actuator 218 and a plurality of arms 230 extending from the central body 228. In some embodiments, the plurality of rods 214 are at least partially disposed within a bellows assembly 224. In some embodiments, the actuator assembly 210 is configured to provide L-motion movement of the slit door 190.

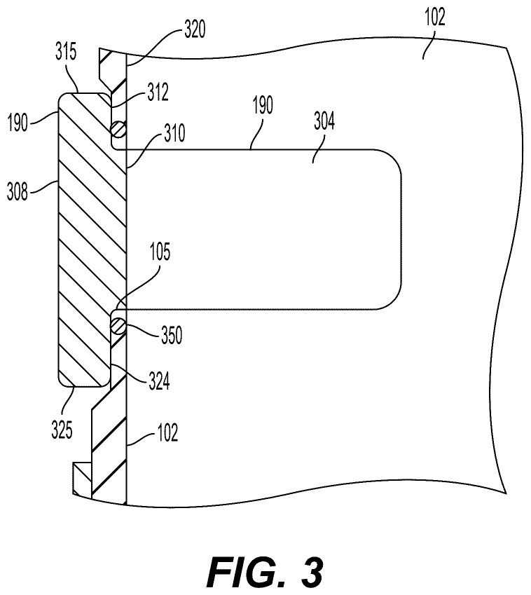

FIG. 3 depicts a cross-sectional view of a slit door 190 and a liner 102 in accordance with at least some embodiments of the present disclosure. The slit door 190 includes a first surface 304 comprising a plasma facing surface and a second surface 308 opposite the first surface. In some embodiments, the plasma facing surface of the slit door 190 comprises a ceramic material or silicon material or is coated with a ceramic material or silicon material, for example yttrium oxide (Y₂O₃). In some embodiments, non-plasma facing surfaces, for example, the second surface 308, an upper surface 315, and a lower surface 325, may be anodized. In some embodiments, the slit door 190 is made of the same material as the liner 102.

As depicted in FIG. 3, the slit door 190 is in a closed position. In the closed position, an inner surface 310 of the slit door 190 is flush, or substantially flush, with an inner surface 320 of the liner 102 to advantageously provide a more uniform plasma facing interface between the liner 102 and the slit door 190. The first surface 304 may include a recessed portion 312 along a peripheral edge of the slit door 190. In some embodiments, the liner 102 includes a recessed portion 324 disposed about the substrate transfer slot 105. In some embodiments, in the closed position, the recessed portion 312 of the slit door 190 abuts the recessed portion 324 of the liner 102. In some embodiments, an RF gasket 350 is disposed between the slit door 190 and the liner 102 to facilitate an RF ground return path between the slit door 190 and the liner 102. In some embodiments, the RF gasket 350 extends around the substrate transfer slot 105.

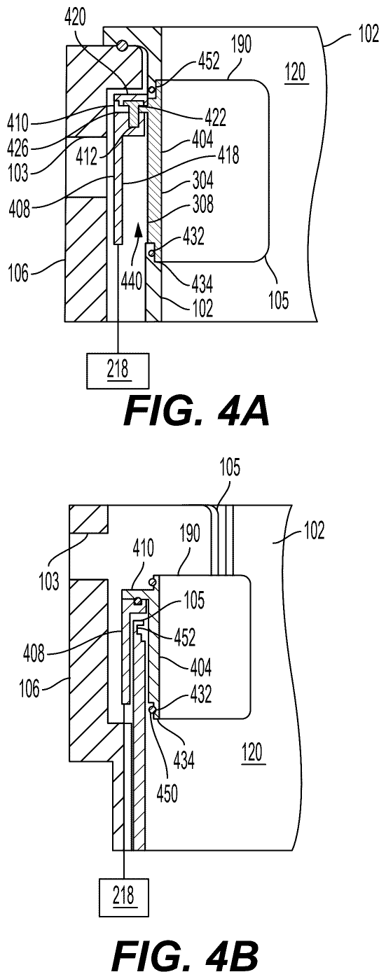

FIG. 4A depicts a cross-sectional view of a slit door 190 and a liner 102 in a closed position in accordance with at least some embodiments of the present disclosure and FIG. 4B depicts a cross-sectional view of the slit door 190 and the liner 102 in an open position in accordance with at least some embodiments of the present disclosure. In some embodiments, as depicted in FIGS. 4A and 4B, the slit door 190 comprises an inner plate 404 coupled to an outer plate 408. The inner plate 404 includes the plasma facing surface, or the first surface 304, and the second surface 308 of the slit door 190. In some embodiments, the inner plate 404 has a height greater than a height of the outer plate 408.

In some embodiments, the inner plate 404 includes a first ledge 410 extending outwardly from the second surface 308. In some embodiments, the first ledge 410 extends outwardly from an upper portion of the second surface 308. In some embodiments, the outer plate 408 includes a second ledge 412 extending inwardly from an inner surface 418 of the outer plate 408 and coupled to the first ledge 410. In some embodiments, the outer plate 408 is coupled to the inner plate 404 via one or more fasteners 422. In some embodiments, the one or more fasteners 422 extend through the first ledge 410 and at least partially through the second ledge 412. In some embodiments, the first ledge 410 is disposed atop the second ledge 412.

In some embodiments, one or more caps 420 are disposed over the one or more fasteners 422 to cover the one or more fasteners 422. The one or more caps 420 may comprise a single cap that covers all of the one or more fasteners 422. In some embodiments, the one or more caps 420 comprise a plurality of caps, where each cap covers a single one of the one or more fasteners 422. A gap 440 is disposed between the inner surface of the outer plate 408 and the second surface 308 of the inner plate 404 sized to accommodate a portion of the liner 102 therein when in the open position.

In some embodiments, an RF gasket 426 is disposed between the first ledge 410 and the second ledge 412 to facilitate RF coupling therebetween. In some embodiments, the second surface 308 includes a recessed portion 432 disposed along a peripheral edge 434 thereof. In some embodiments, an RF gasket 450 is disposed in the recessed portion 432. In some embodiments, the liner 102 includes a recessed portion 452 to accommodate the RF gasket 450. In some embodiments, the recessed portion 452 may also accommodate the peripheral edge 434 of the slit door 190. The improved RF return path via the RF gasket 450 and the RF gasket 426 advantageously increases process uniformity and reduces process skew.

In use, in the closed position, an inner surface of the inner plate 404 is flush, or substantially flush, with an inner surface of the liner 102. The flush interface between the slit door 190 and the liner 102 advantageously improves process uniformity and improves electrical current flow. In the open position, the slit door 190 extends radially inward and downward so that the liner 102 extends between the inner plate 404 and the outer plate 408 (i.e., in the gap 440) and the opening 103 in the chamber body 106 is exposed for transferring the substrate 122. In other words, in the open position, the inner plate 404 is disposed radially inward of sidewalls of the liner 102 and the outer plate 408 is disposed radially outward of the sidewalls of the liner 102.

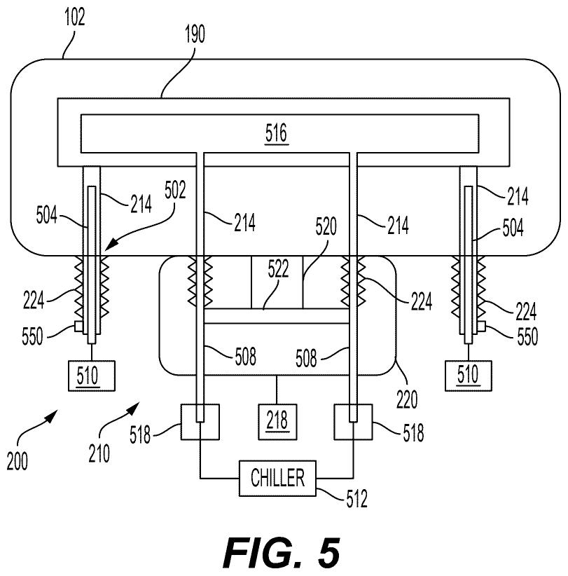

FIG. 5 depicts a schematic back view of a slit door assembly 200 in accordance with at least some embodiments of the present disclosure. In some embodiments, the slit door assembly 200 includes cooling and/or heating features to control a temperature of the slit door 190. For example, the temperature of slit door 190 can be controlled to be uniform with the liner 102 to improve process uniformity. In some embodiments, the plurality of rods 214 include one or more rods having a cooling channel 508 configured to supply a coolant to the slit door 190. In some embodiments, the slit door 190 includes a cooling channel 516 coupled to the cooling channel 508 to circulate the cooling within the slit door 190.

In some embodiments, as shown in FIG. 5, the plurality of rods 214 comprise a rod having a cooling channel 508 extending from a chiller 512 to the cooling channel 516 in the slit door 190 and a different rod having a cooling channel 508 for returning the coolant from the cooling channel 516 back to the chiller 512. The chiller 512 may be any suitable machine for removing heat, (i.e., cooling), the coolant. In some embodiments, the coolant is a liquid coolant such as water, ethylene glycol, a perfluoropolyether fluorinated fluid such as Galden®, a registered trademark own by Solvay Specialty Polymers of Bollate, Italy, or the like, or a cooling gas such as cool air. In some embodiments, the cooling channel 508 includes a supply channel extending from the chiller 512 to the cooling channel 516 and a return channel extending from the cooling channel 516 back to the chiller 512. In some embodiments, a fitting 518 is disposed at a lower end of each of the plurality of rods 214 having the cooling channel 508 to facilitate connection to the chiller 512.

In some embodiments, the plurality of rods 214 comprise one or more rods having a heater 502. In some embodiments, the heater 502 comprises a resistive heating element such as a fire rod 504 disposed in the one or more rods. The fire rod 504 may comprise a metal rod coupled to a power source 510, for example a controllable DC power supply, configured to heat the metal rod by passing electrical energy therethrough. The heater 502 may include a thermocouple 550 to monitor the temperature of the fire rod 504 and facilitate controlling the temperature of the fire rod 504 through a temperature controller. The one or more rods having the heater 502 may be disposed at two ends of the slit door 190. In some embodiments, the heater 502 may be a thermal blanket disposed about the one or more rods.

In some embodiments, the plurality of rods 214 include four rods, wherein two of the four rods are coupled to the bracket 220 and have the cooling channel 508 and two of the four rods are spaced from the bracket 220 and have the heater 502. In some embodiments, the one or more rods having the heater 502 are coupled to the bracket 220. In some embodiments, the bracket 220 includes a block 520 that provides a hard stop 522 for the actuator 218. The plurality of rods 214 may include a bellows assembly 224 disposed along at least a portion of each of the plurality of rods 214 to protect the rods and/or facilitate vertical movement of the plurality of rods 214 with respect to the liner 102.

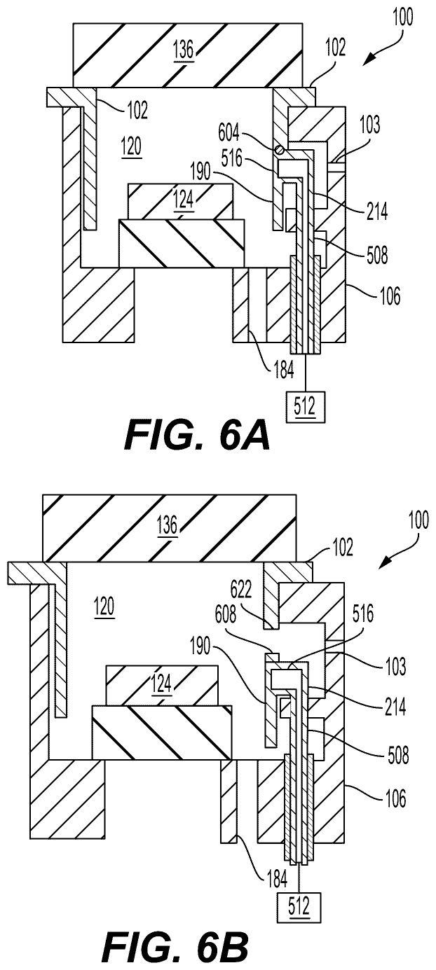

FIG. 6A depicts a schematic cross-sectional side view of a process chamber 100 with a slit door 190 in a closed position in accordance with at least some embodiments of the present disclosure. FIG. 6B depicts a schematic cross-sectional side view of a process chamber 100 with a slit door 190 in an open position in accordance with at least some embodiments of the present disclosure. The views of FIGS. 6A and 6B are taken along one of the plurality of rods 214.

In the closed position, the slit door 190 abuts a transfer slot 622 of the liner 102. In the opening position, the slit door 190 is spaced from the transfer slot 622 of the liner 102. In some embodiments, a heat transfer pad 604 is disposed atop the slit door. The heat transfer pad 604 facilitates improved heat transfer between the slit door 190 and the liner 102. In some embodiments, a high plasma-resistant damping pad 608 is disposed the slit door 190 and the liner 102, such as atop the slit door 190 so that in the closed position, the high plasma-resistant damping pad 608 reduces or prevents plasma leak between the liner 102 and the slit door 190. In some embodiments, the high plasma-resistant damping pad 608 comprises a ceramic or plastic material. In some embodiments, the heat transfer pad 604 and the high plasma-resistant damping pad 608 is disposed between the liner 102 and the slit door 190.

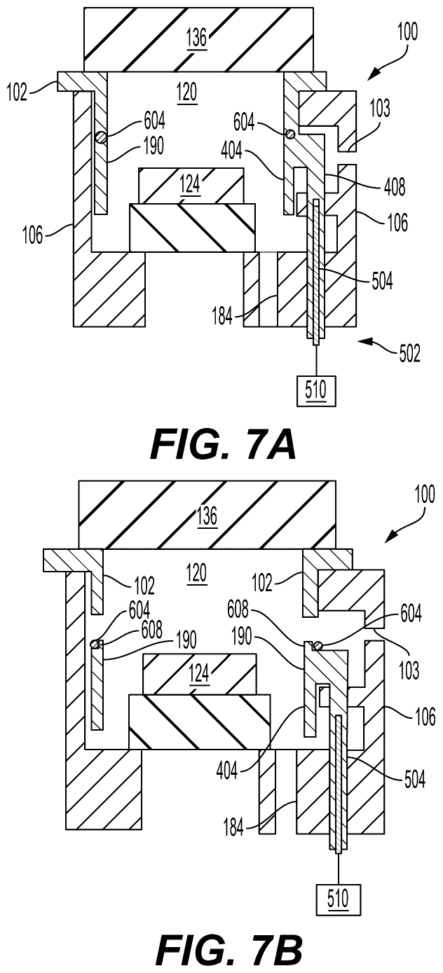

FIG. 7A depicts a schematic cross-sectional side view of a process chamber 100 with an annular slit door in a closed position in accordance with at least some embodiments of the present disclosure. FIG. 7B depicts a schematic cross-sectional side view of a process chamber 100 with an annular slit door in an open position in accordance with at least some embodiments of the present disclosure. The views of FIGS. 7A and 7B are taken along one of the plurality of rods 214 having the heater 502. In some embodiments, as depicted in FIGS. 7A and 7B, the slit door 190 has an annular shape. The slit door 190 having an annular shape may include any of the features discussed above with respect to the slit door 190 having an arcuate shape, such as the interface with the liner 102, heating and cooling features, or the like. In such embodiments, the heat transfer pad 604 may be annular in shape. In such embodiments, the high plasma-resistant damping pad 608 may be annular in shape. In some embodiments, the slit door 190 that is annular in shape includes the heater 502 disposed at regular intervals about the slit door 190, for example, three heaters disposed about 120 degrees from each other, four heaters disposed about 90 degrees from each other, or the like, about a center of the slit door 190.

While the foregoing is directed to embodiments of the present disclosure, other and further embodiments of the disclosure may be devised without departing from the basic scope thereof.

1. A slit door assembly for use in a process chamber, comprising:
a slit door having an arcuate profile and a first surface comprising a plasma facing surface and a second surface opposite the first surface, and wherein at least one of:
the first surface or the second surface includes a recessed portion along a peripheral edge thereof; or
the slit door has an annular shape; and
an actuator assembly coupled to the slit door and configured to move the slit door in a vertical direction, wherein the actuator assembly includes a plurality of rods coupled to the slit door, wherein one or more of the plurality of rods include a cooling channel extending to the slit door or a heater.

2. The slit door assembly of claim 1, wherein the plasma facing surface comprises a coating comprising a ceramic material or silicon material.

3. The slit door assembly of claim 1, wherein one or more of the plurality of rods include the cooling channel extending to the slit door.

4. The slit door assembly of claim 1, wherein one or more of the plurality of rods include the heater.

5. The slit door assembly of claim 1, wherein the plurality of rods include four rods, and wherein two rods are coupled to a bracket and have a cooling channel, and two rods are spaced from the bracket and have a heater.

6. The slit door assembly of claim 1, further comprising a high plasma-resistant damping pad disposed atop the slit door.

7. The slit door assembly of claim 1, wherein the slit door comprises an inner plate and an outer plate, wherein the inner plate includes the plasma facing surface and the second surface of the slit door, wherein the inner plate includes a first ledge extending outwardly from the second surface, and the outer plate includes a second ledge extending inwardly from an inner surface of the inner plate and coupled to the first ledge, and wherein a gap is disposed between the inner surface of the inner plate and the second surface.

8. The slit door assembly of claim 7, wherein the inner plate has a height greater than a height of the outer plate.

9. The slit door assembly of claim 1, further comprising an RF gasket disposed in the recessed portion.

10. The slit door assembly of claim 1, further comprising a heat transfer pad disposed atop the slit door.

11. A process kit for use in a process chamber, comprising:
a liner having an annular shape and a transfer slot; and
a slit door assembly, comprising:
a slit door having an arcuate profile and a first surface comprising a plasma facing surface and a second surface opposite the first surface; and
an actuator assembly coupled to the slit door and configured to move the slit door in a vertical direction to selectively place the slit door in a closed position, where the slit door is in contact with the liner, and an open position, where the slit door is spaced from the liner, and wherein in the closed position, an inner surface of the slit door is substantially flush with an inner surface of the liner to close the transfer slot.

12. The process kit of claim 11, wherein the first surface or the second surface includes a recessed portion along a peripheral edge thereof.

13. The process kit of claim 11, wherein the plasma facing surface comprises a ceramic material or silicon material.

14. The process kit of claim 11, wherein the slit door includes an inner plate coupled to an outer plate, and wherein in the open position, the inner plate is disposed radially inward of sidewalls of the liner and the outer plate is disposed radially outward of the sidewalls of the liner.

15. The process kit of claim 11, wherein the actuator assembly includes a plurality of rods, wherein one or more rods include a cooling channel and one or more rods include a heater.

16. The process kit of claim 15, wherein the heater comprises a fire rod.

17. A process chamber, comprising:
a chamber body defining an interior volume therein, having an opening extending through sidewalls of the chamber body for transferring a substrate, and having a chamber cavity disposed about the opening on an interior surface of the chamber body;
the process kit of claim 11, wherein the transfer slot of the liner is aligned with the opening in the chamber body, and wherein at least one of:
the first surface or the second surface includes a recessed portion along a peripheral edge thereof; or
the slit door has an annular shape; and
a substrate support disposed in the interior volume to support a substrate.

18. The process chamber of claim 17, wherein the actuator assembly includes a plurality of rods, wherein one or more of the plurality of rods include a cooling channel extending to the slit door.

19. The process chamber of claim 17, wherein the actuator assembly includes a plurality of rods, wherein one or more of the plurality of rods include a heater.

20. The process chamber of claim 17, wherein the transfer slot includes the recessed portion along an edge of the transfer slot, and wherein in the closed position, the recessed portion of the slit door abuts a surface of the recessed portion of the liner.
